(19) United States
(12) Patent Application Publication
(10) Pub. No.: US 2011/0151132 A1
(43) Pub. Date: Jun. 23, 2011

(54) Methods for Coating Articles Exposed to Hot and Harsh Environments

(76) Inventors: Bangalore Nagaraj, West Chester, OH (US); Terry Lee Few, Cincinnati, OH (US); Timothy P. McCaffrey, Swampscott, MA (US); Brian P. L. Heureux, Melrose, MA (US)

(21) Appl. No.: 12/751,690

(22) Filed: Mar. 31, 2010

Related U.S. Application Data
(60) Provisional application No. 61/288,476, filed on Dec. 21, 2009.
(60) Provisional application No. 61/288,486, filed on Dec. 21, 2009.
(60) Provisional application No. 61/288,490, filed on Dec. 21, 2009.

(51) Int. Cl. C23C 16/40; C23C 16/513; C23C 14/34

(52) U.S. Cl. 427/454; 427/576; 204/192.15

(57) ABSTRACT

Methods for providing a coating system for reducing CMAS infiltration of substrates exposed to hot and harsh climates. Exemplary methods include optionally disposing a bond coat on a substrate, disposing an inner ceramic layer over the bond coat, or on the substrate in the absence of a bond coat, and disposing an outer alumina-containing layer including up to 50 percent by weight titania, using a high velocity oxygen fuel (HVOF) technique. Additional ceramic layers and alumina-containing layers may be provided to achieve a CMAS resistant coating. One or more suitable heat treatments may be utilized to phase-stabilize the alumina. The coating may be used for gas turbine engine components. Deposition techniques for the ceramic layer(s) may depend on the end use of the component.

### CROSS REFERENCE TO RELATED APPLICATIONS

This Application claims priority and benefit of U.S. Provisional Patent Application Ser. No. 61/288,476, filed Dec. 21, 2009; U.S. Provisional Patent Application Ser. No. 61/288,486, filed Dec. 21, 2009; and U.S. Provisional Patent Application Ser. No. 61/288,490, filed Dec. 21, 2009, the disclosures of which are incorporated herein by reference in their entirety.

### BACKGROUND OF THE INVENTION

This invention generally relates to methods for coating articles adapted for exposure to high temperatures, such as the hostile thermal environment of a gas turbine engine. More particularly, this invention is directed to methods for providing a coating system comprising an alumina-containing layer applied over a ceramic thermal barrier coating layer.

The efficiency of the engine is directly related to the temperature of the combustion gases. High temperature capability superalloy metals may be utilized for those components exposed to the harshest thermal environments. For example, combustor liners may be comprised of a nickel base superalloy. The combustor liner may be conventionally protected from the hot combustion gases by having the inboard surfaces thereof covered by a thermal barrier coating (TBC). Conventional thermal barrier coatings include ceramic materials which provide a thermal insulator for the inboard surfaces of the combustor liner which directly face the hot combustion gases. Combustor liners are merely exemplary of the types of components exposed to hostile thermal conditions for which improved thermal protection is sought.

Ceramic materials and particularly yttria-stabilized zirconia (YSZ) are widely used as TBC materials because of their high temperature capability, low thermal conductivity, and relative ease of deposition by plasma spraying, flame spraying and physical vapor deposition (PVD) techniques. Air plasma spraying (APS) has the advantages of relatively low equipment costs and ease of application and masking, while TBCs employed in the highest temperature regions of gas turbine engines are often deposited by PVD, particularly electron-beam PVD (EBPVD), which yields a strain-tolerant columnar grain structure.

The service life of a TBC system is typically limited by a spallation event brought on by thermal fatigue. In addition to the CTE mismatch between a ceramic TBC and a metallic substrate, spallation can occur as a result of the TBC structure becoming densified with deposits that form on the TBC during gas turbine engine operation. Notable constituents of these deposits include such oxides as calcia, magnesia, alumina and silica, which when present together at elevated temperatures form a compound referred to herein as CMAS. CMAS has a relatively low melting eutectic (about 1190° C.) that when molten is able to infiltrate the hotter regions of a TBC, where it resolidifies during cooling. During thermal cycling, the CTE mismatch between CMAS and the TBC promotes spallation. The loss of the TBC results in higher temperature exposure for the underlying substrate, accelerating oxidation and poor creep and low cycle fatigue performance.

Further improvements in preventing the damage inflicted by CMAS infiltration are continuously sought.

### BRIEF DESCRIPTION OF THE INVENTION

The above-mentioned needs may be met by exemplary embodiments that provide coating systems for components utilized in hot and harsh environments. The protected component may be suitable for use in a high-temperature environment such as the hot section of a gas turbine engine. Exemplary embodiments may be particularly useful in preventing or mitigating the effects of CMAS infiltration.

A method comprises providing a substrate, optionally, disposing a bond coat on at least a portion of the substrate, and providing a coating over the bond coat, or onto the substrate in the absence of a bond coat. The coating includes an inner ceramic layer and an outer alumina-containing layer outward of the inner ceramic layer, wherein the outer alumina-containing layer includes titania in an amount greater than 0% up to about 50% by weight. The inner ceramic layer is provided by using a technique selected from a thermal spray technique, a physical vapor deposition technique, and a solution plasma spray technique. The outer alumina-containing layer is provided by using a technique selected from a suspension plasma spray, a solution plasma spray technique, and a high velocity oxygen fuel technique.

### BRIEF DESCRIPTION OF THE DRAWINGS

The subject matter which is regarded as the invention is particularly pointed out and distinctly claimed in the concluding part of the specification. The invention, however, may be best understood by reference to the following description taken in conjunction with the accompanying drawing figures in which:

FIG. 1 is an axial sectional view of a portion of an exemplary annular combustor in a gas turbine engine.

FIG. 2 is a representation of an article coated with an exemplary coating system as disclosed herein.

FIG. 3 is a representation of an article coated with an alternate exemplary coating system as disclosed herein.

FIG. 4 is a flowchart representing an exemplary process as disclosed herein.

### DETAILED DESCRIPTION OF THE INVENTION

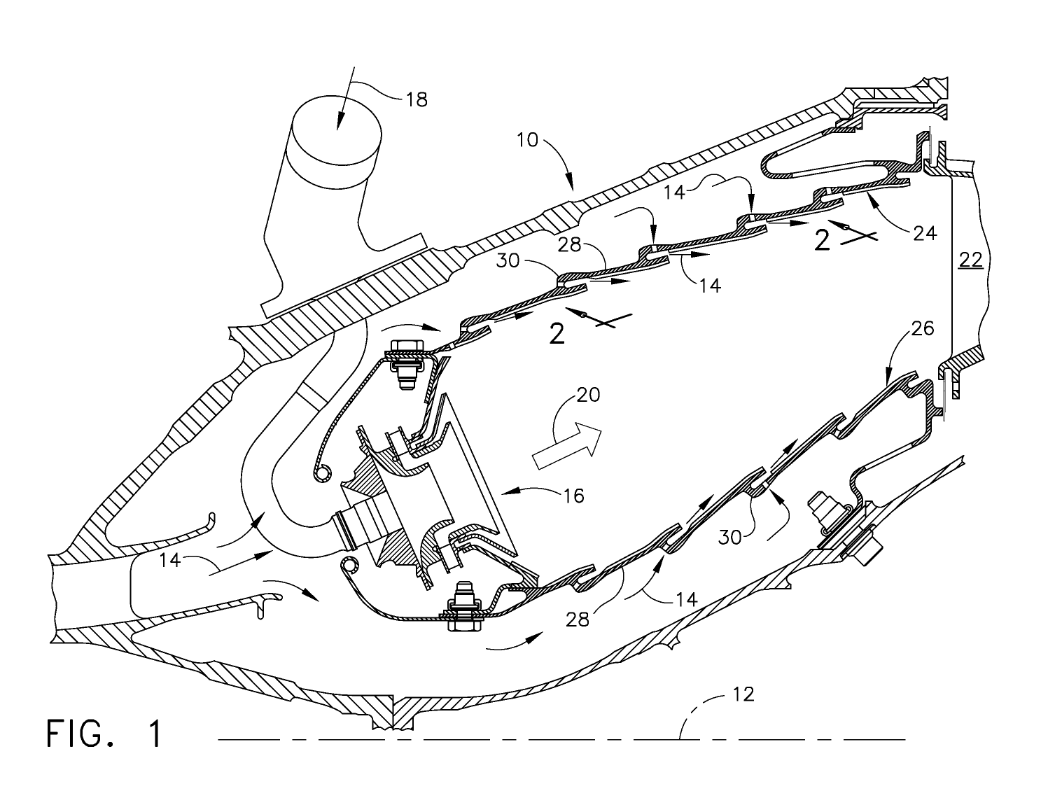

Referring to the drawings wherein identical reference numerals denote the same elements throughout the various views, FIG. 1 illustrates an annular combustor 10 that is axisymmetrical about a longitudinal or axial centerline axis 12. The combustor is suitably mounted in a gas turbine engine having a multistage axial compressor (not shown) configured for pressurizing air 14 during operation. A row of carburetors 16 introduces fuel 18 into the combustor that is ignited for generating hot combustion gases 20 that flow downstream therethrough.

A turbine nozzle 22 of a high pressure turbine is disposed at the outlet end of the combustor for receiving the combustion gases, which are redirected through a row of high pressure turbine rotor blades (not shown) that rotate a disk and shaft for powering the upstream compressor. A low pressure turbine (not shown) is typically used for extracting additional energy for powering an upstream fan in a typical turbofan aircraft gas turbine engine application, or an output shaft in a typical marine and industrial application.

The exemplary combustor 10 includes an annular, radially outer liner 24, and an annular radially inner liner 26 spaced radially inwardly therefrom for defining an annular combustion chamber therebetween through which the combustion gases 20 flow. The upstream ends of the two liners 24, 26 are joined together by an annular dome in which the carburetors 16 are suitably mounted.

The two liners 24, 26 have inboard surfaces, concave and convex, respectively, which directly face the combustion gases 20, and are similarly configured. Accordingly, the following description of the outer liner 24 applies equally as well to the inner liner 26 recognizing their opposite radially outer and inner locations relative to the combustion chamber which they define.

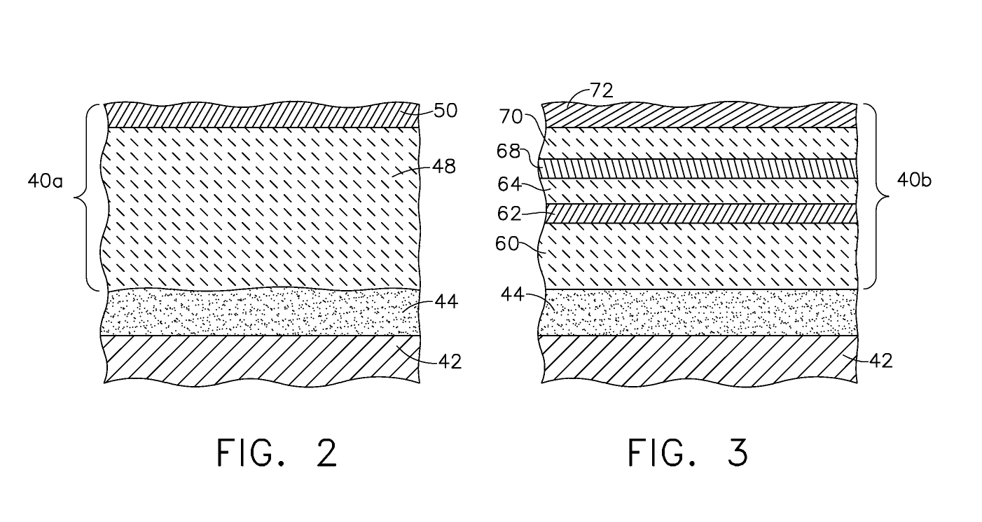

Certain regions of the liners 24, 26 may be provided with an exemplary coating system 40. Alternate embodiments of the coating system are illustrated with more particularity as coating systems 40a and 40b in FIGS. 2-3, respectively.

FIG. 2 illustrates an exemplary coating system 40a as applied to a substrate 42 representative of combustor liners 24, 26 or other component adapted for use in a high temperature environment. Substrate 42 may optionally be coated with a bond coat 44. The bond coat 44 may comprise an overlay coating, for example, MCrAlX, where M is iron, cobalt and/or nickel, and X is an active element such as yttrium or another rare earth or reactive element. MCrAlX materials are referred to as overly coatings because they are generally applied in a predetermined composition and do not interact significantly with the substrate during the deposition process. Substrate 42 may be comprised of a superalloy material such as a nickel base superalloy.

In other exemplary embodiments, the bond coat 44 may comprise what is known in the art as a diffusion coating such as Al, PtAl, and the like. Material for forming the bond coat may be applied by any suitable technique capable of producing a dense, uniform, adherent coating of the desired composition. Such techniques may include, but are not limited to, diffusion processes, low pressure plasma spray, air plasma spray, sputtering, cathodic arc, electron beam physical vapor deposition, high velocity plasma spray techniques (e.g., HVOF, HVAF), combustion processes, wire spray techniques, laser beam cladding, electron beam cladding, etc. In certain embodiments, it may be desirable for the bond coat 44 to exhibit a desired surface roughness to promote adhesion of the thermal barrier coating.

In an exemplary embodiment, the substrate is provided with a ceramic coating layer 48 generally overlaying the bond coat, if present. The ceramic layer 48 is formed from a ceramic based compound as is known to those of ordinary skill in the art. Representative compounds include, but are not limited to, any stabilized zirconate, any stabilized hafnate, combinations comprising at least one of the foregoing compounds, and the like. Examples include yttria stabilized zirconia, calcia stabilized zirconia, magnesia stabilized zirconia, yttria stabilized hafnia, calcia stabilized hafnia and magnesia stabilized hafnia. Certain exemplary embodiments include what is termed in the art as “low conductivity TBC” including zirconia plus oxides of yttrium, gadolinium, ytterbium and/or tantalum that exhibit lower thermal conductivity than zirconia partially stabilized with 7 weight percent yttria, commercially known as 7YSZ.

The ceramic based compound may be applied to the substrate using any number of processes known to those of skill in the art. Suitable application processes include but are not limited to, physical vapor deposition, thermal spray, sputtering, sol gel, slurry, combinations comprising at least one of the foregoing application processes, and the like.

Those with skill in the art will appreciate that a thermal barrier coating applied using an electron beam physical vapor deposition (EB-PVD) process forms an intercolumnar microstructure exhibiting free standing columns with interstices formed between the columns. Also, as recognized by one of ordinary skill in the art, a thermal barrier coating applied via a thermal spray process exhibits a tortuous, interconnected porosity due to the splats and microcracks formed during the thermal spray process. Thus, in certain instances, it is possible to determine the mode of application based on the microstructure of the coating layers.

In an exemplary embodiment, ceramic layer 48 is applied using EB-PVD in particular for parts having an airfoil, such as a turbine blade, and thus exhibits an associated intercolumnar microstructure. In another exemplary embodiment, ceramic layer 48 is applied using a thermal spray technique (e.g., air plasma spray) in particular for combustor liners, and thus exhibits an associated non-columnar, irregular flattened grain microstructure.

In an exemplary embodiment, the coating system 40a includes an outermost alumina-containing layer 50. In an exemplary embodiment, the alumina-containing layer 50 is applied using an HVOF technique. In other certain exemplary embodiments, the outermost layer 50 may be provided via a suspension plasma spray or a solution plasma spray technique. In an exemplary embodiment the alumina-containing layer 50 may be deposited by a composition comprising substantially all alumina (about 100% by weight). In an exemplary embodiment, the outermost layer 50 includes titania (TiO2) in amounts greater than 0 to about 50% by weight with the balance being substantially alumina (Al2O3). Certain exemplary embodiments include from about 30-50 weight % titania, balance alumina. As used herein, values presented as ranges are inclusive of endpoints and all sub-ranges. For example, the range 30-50 weight percent includes 30%, 50%, and all sub-ranges of values between 30 and 50%. Other embodiments include from about 40-50 weight % titania, balance alumina.

By way of example, HVOF can be used to deposit the alumina-containing layer 50 onto the ceramic layer 48. The heat source includes a flame and a thermal plume controlled by the input gases, fuels, and nozzle designs. Oxygen and fuel are supplied at high pressure such that the flame issues from a nozzle at supersonic velocity. The alumina-containing layer 50 may be deposited under ambient conditions.

In an exemplary embodiment, the bond coat 44 may be provided at a thickness sufficient to adhere the coating system 40a, and in particular ceramic layer 48, to the substrate 42. In an exemplary embodiment, bond coat 44 is provided at a nominal thickness of about 127 microns (5 mils). Other bond coat thicknesses may be utilized in order to achieve the desired results. All coating layer thicknesses of the exemplary coating systems provided herein are given by way of example, and not by way of limitation. Use of the term “nominal thickness” describes a target, as deposited thickness. The actual deposited thickness may vary within acceptable tolerance levels.

The ceramic layer 48 may be provided at a thickness sufficient to provide a desired thermal protection for the underlying substrate 42. In an exemplary embodiment, the ceramic layer 48 may be nominally about 508 microns (20 mils) thick. In other exemplary embodiments, the ceramic layer may be provided with a nominal thickness either less than or greater than 508 microns, as the situation may warrant within the scope of this disclosure.

In an exemplary embodiment, the alumina-containing layer 50 may be provided at a thickness sufficient to provide a desired CMAS infiltration mitigation. In an exemplary embodiment, layer 50 may have a nominal thickness of about 25 microns (1 mil). Thus, coating system 40a may have a nominal total thickness of about 533 microns (21 mils). Bond coat 44 may have a thickness of about 127 microns (5 mils).

An alternate embodiment includes a multi-layered coating system applied to a substrate. In general terms, the multi-layered coating system comprises one or more alumina-containing layers interleaved between ceramic layers, in addition to the outermost alumina-containing layer. One particular embodiment of the multi-layered coating system 40b is shown by example in FIG. 3.

As illustrated, the substrate 42 may be provided with a bond coat 44, discussed above. Substrate 42 is provided with an inner ceramic layer 60 that overlies and contacts the bond coat 44, if present, or the substrate in the absence of a bond coat. The composition of the inner ceramic layer 60 may be similar to previously described ceramic layer 48. Inner layer 60 may be provided with a nominal thickness less than ceramic layer 48. In an exemplary embodiment, inner layer 60 has a nominal thickness of about 305 microns (12 mils). In other exemplary embodiments, the thickness of inner layer 60 may be between about 203-355 microns (about 8-14 mils). In other exemplary embodiments, the thickness of inner layer 60 is at least about 254 microns (10 mils). Inner layer 60 may be deposited by an air plasma spray, EB-PVD, or other deposition technique as discussed above, depending on the desired microstructure and/or thickness.

In an exemplary embodiment, the multi-layer coating system 40b includes a first intermediate alumina-containing layer 62 overlying and in contact with inner layer 60. In an exemplary embodiment, the first intermediate alumina-containing layer 62 may be deposited from a similar composition to that used in providing alumina-containing layer 50 as described earlier. Alumina-containing layer 62 may include titania in any amount up to about 50% by weight, with the balance being alumina (i.e., up to 1:1 weight ratio of titania to alumina). In an exemplary embodiment, the first intermediate alumina-containing layer 62 is provided at a nominal thickness of about 25 microns (1 mil). Thicknesses greater than or less than 25 microns are contemplated within the scope of the invention. In an exemplary embodiment, alumina-containing layer 62 is provided using a HVOF technique. All percentages used herein are given “by weight” unless indicated otherwise.

In an exemplary embodiment, a first intermediate ceramic layer 64 overlies and contacts the first intermediate alumina-containing layer 62. The first intermediate ceramic layer 64 may be substantially similar in composition to the inner ceramic layer 60. In an exemplary embodiment, the first intermediate ceramic layer 64 is applied at a nominal thickness of about 51 microns (2 mils). Layer 64 may be deposited by air plasma spray, EB-PVD, or other deposition technique, depending on the desired microstructure and/or thickness.

An exemplary embodiment includes second intermediate alumina-containing layer 68 overlying and in contact with the first intermediate ceramic layer 64. Layer 68 may be formed of a similar composition to layer 62, although in certain exemplary embodiments, the titania/alumina ratio may be higher or lower than the titania/alumina ratio of layer 62. In an exemplary embodiment, second intermediate alumina-containing layer 68 is formed from a composition having about 50% titania and 50% alumina. In an exemplary embodiment, alumina-containing layer 68 is provided at a nominal thickness of about 25 microns (1 mil). In an exemplary embodiment, layer 68 is provided through a HVOF technique.

The exemplary embodiment illustrated in FIG. 3 includes second intermediate ceramic layer 70 generally overlying and in contact with the alumina-containing layer 68. In an exemplary embodiment, layer 70 may be substantially similar in composition to layer 60 and/or layer 64. In another exemplary embodiment, layer 70 may be a “transitional layer” comprising a compositional gradient. Layer 70 may be deposited using a thermal spray process. In other exemplary embodiments, layer 70 may be deposited in a physical vapor deposition process such as EB-PVD. In certain exemplary embodiments, it may be beneficial for layer 70 to be more porous than layer 68 and/or layer 64. In an exemplary embodiment, layer 70 may be provided at a nominal thickness of about 51 microns (2 mils).

In an exemplary embodiment, coating system 40b includes an outer alumina-containing layer 72. Layer 72 may be provided from a coating composition similar to that used in providing alumina-containing layer 62 and/or layer 68. In an exemplary embodiment, layer 72 may be substantially alumina (i.e., 100% by weight). Other exemplary embodiments include titania in amounts greater than 0% and up to about 50% by weight. In an exemplary embodiment, layer 72 is provided at a nominal thickness of about 25 microns (1 mil). The thickness of any of the coating layers disclosed herein may be provided at other nominal values in order to achieve a desired result. In an exemplary embodiment, the outermost alumina-containing layer 72 is provided using a HVOF technique.

Generally, titania may be added to the alumina-containing layer in an amount sufficient to change the modulus of the coating layer to improve flexibility as compared to alumina alone. The addition of titania does not diminish the CMAS infiltration mitigation realized by an alumina layer.

In still other alternate embodiments, the alumina-containing layer(s) (e.g., alumina or alumina/titania) disclosed herein may be deposited using a suspension plasma spray, solution plasma spray, or high velocity air plasma spray process. Certain characteristics of the coating layers, such as the as-deposited microstructure, may be indicative of the deposition technique.

Any of the thermal barrier coating layers disclosed herein may comprise a so-called low conductivity thermal barrier composition comprising zirconia plus oxides of yttrium, gadolinium, ytterbium, and/or tantalum.

Additionally, it may be beneficial to control the phase transformation, and therefore the volume change, of the alumina-containing layer(s) prior to use of the component in service. Therefore, the coated article may be subjected to one or more appropriate heat treatments to ensure that substantially all the alumina is converted to α-alumina. An exemplary heat treatment may include one or more passes of the thermal spray equipment without any powder deposition. Alternately, the component may be vacuum heat treated in a furnace at a temperature in the range of about 2000 to 2200° F. for from about one to four hours. Exemplary embodiments may include a phase-stabilizing heat treatment following each deposition of the alumina-containing layers (for example in multi-layered coating systems), or a single phase-stabilizing heat treatment may be utilized.

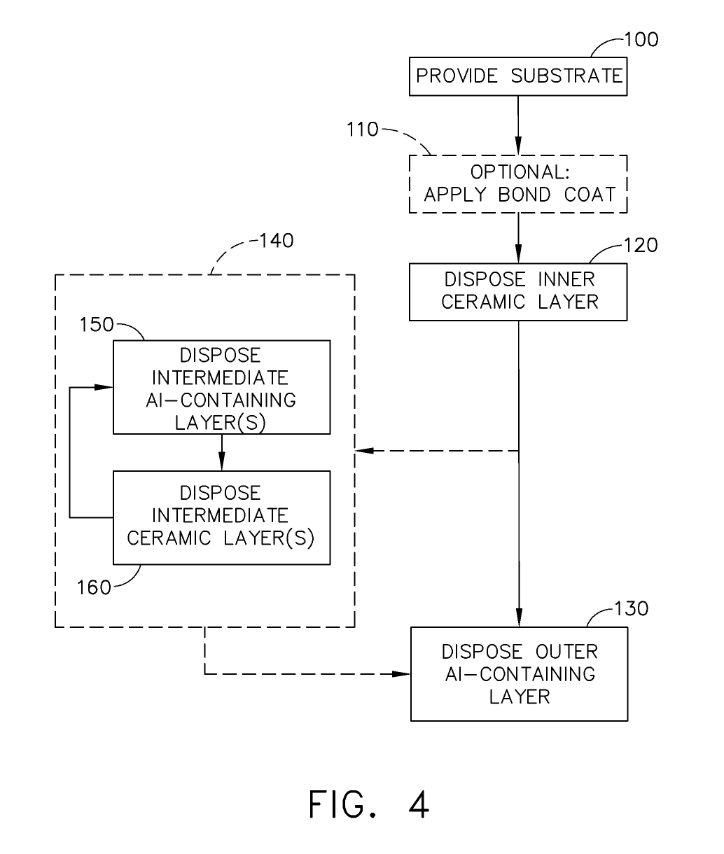

FIG. 4 provides a summary of exemplary processes. In an exemplary process, a substrate is provided (Step 100). Exemplary substrates may include combustor liners, airfoils, or other components for use in high temperature environments. The substrate may comprise a superalloy such as a nickel base superalloy. A portion of the substrate may be provided with an optional bond coat (Step 110). Suitable bond coats include overlay bond coats (e.g., MCrAlX) and diffusion bond coats (e.g., aluminide type bond coats). In an exemplary process, a first ceramic layer is disposed on the bond coat, or the substrate in the absence of a bond coat (Step 120). The process used to provide the first ceramic layer may be dependent on the desired microstructure and/or substrate type, as explained more fully above.

In an exemplary process, an outermost aluminum-containing layer is provided (Step 130). The outer aluminum-containing layer may be substantially all aluminum, or may include up to about 50% by weight titania.

In an exemplary process, additional layers may optionally be provided (Step 140) as indicated by a dashed box in FIG. 4. Providing additional layers may include disposing additional alumina-containing layer(s) (Step 150) and additionalceramic layer(s) (Step 160) prior to providing the outermost aluminum-containing layer in Step 130. An intermediate layer may also be compositionally graded with alumina and/or alumina/titania and ceramic material. In an exemplary embodiment, he compositionally graded layer may include a higher ceramic content near the ceramic layer interface, and gradually increase in alumina or alumina/titania content with the thickness of the layer.

As discussed above, exemplary processes may further include one or more phase-stabilizing heat treatments to convert the as-deposited alumina to stable α-alumina form.

### Example 1

A multi-layered coating system on a substrate (or on a bond coated substrate) includes an inner ceramic layer consisting substantially of yttria stabilized zirconia having a thickness of from about 127 to about 254 microns (about 5 to about 10 mils). A first intermediate alumina-containing layer overlying the inner layer consists substantially of alumina or alumina and up to about 50% by weight titania deposited by an HVOF technique to a thickness of from about 25 to about 51 microns (about 1 to 2 mils). A first intermediate ceramic layer overlying the first intermediate alumina-containing layer consists substantially of yttria stabilized zirconia having a thickness of from about 127 to about 254 microns (about 5 to about 10 mils). An outer alumina-containing layer overlying the first intermediate ceramic layer consists substantially of alumina or alumina and up to about 50% by weight titania, deposited to a thickness of about 25 to about 51 microns (about 1-2 mils) utilizing an HVOF technique.

### Example 2

A multi-layered coating system on a substrate (or a bond coated substrate) includes an inner ceramic layer consisting substantially of yttria stabilized zirconia having a thickness of from about 127 to about 254 microns (about 5 to about 10 mils). A first intermediate alumina-containing layer overlying the inner ceramic layer includes an air plasma sprayed graded layer having a thickness of from about 127 to about 254 microns (about 5-10 mils) 50% by weight alumina (or alumina/titania) the balance yttria stabilized zirconia and increasing the content of alumina (or alumina/titania) in the intermediate alumina-containing layer. An outer alumina or alumina/titania layer is applied using an HVOF technique to a thickness of from about 25 to about 51 microns (about 1-2 mils).

This written description uses examples to disclose the invention, including the best mode, and also to enable any person skilled in the art to make and use the invention. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. A method comprising:
providing a substrate;
optionally, disposing a bond coat on at least a portion of the substrate;
providing a coating over the bond coat, or onto the substrate in the absence of a bond coat, wherein the coating includes an inner ceramic layer and an outer alumina-containing layer outward of the inner ceramic layer, wherein the outer alumina-containing layer includes titania in an amount greater than 0% up to about 50% by weight; and
wherein the inner ceramic layer is provided by using a technique selected from a thermal spray technique, a physical vapor deposition technique, and a solution plasma spray technique; and
wherein the outer alumina-containing layer is provided by using a technique selected from a suspension plasma spray, a solution plasma spray technique, and a high velocity oxygen fuel technique.

2. The method according to claim 1 including a suitable heat treatment operable to provide substantially all the alumina in the outer alumina-containing layer as an α-alumina form.

3. The method according to claim 1 wherein providing the coating includes:
providing at least a first intermediate alumina-containing layer between the inner ceramic layer and the outer alumina-containing layer, wherein the intermediate alumina-containing layer comprises substantially all alumina or alumina/titania being up to about 50 percent by weight titania; and
providing at least a first intermediate ceramic layer between the first intermediate alumina-containing layer and the outer alumina-containing layer.

4. The method according to claim 3 including one or more suitable heat treatments operable to provide substantially all the alumina in the first intermediate alumina-containing layer and in the outer alumina-containing layer as an α-alumina form.

5. The method according to claim 1 comprising:
providing at least a first intermediate alumina-containing layer between the inner ceramic layer and the outer alumina-containing layer, wherein the intermediate alumina-containing layer is comprised of a compositional gradient of a ceramic composition and an alumina-containing composition, wherein the ceramic composition is higher near an interface of the first intermediate alumina-containing layer and the inner ceramic layer; and
providing at least a first intermediate ceramic layer disposed between the first intermediate alumina-containing layer and the outer alumina-containing layer.

6. The method according to claim 1 wherein providing the inner ceramic layer comprises providing at least one member of the group consisting of yttria stabilized zirconia, calcia stabilized zirconia, magnesia stabilized zirconia, yttria stabilized hafnia, calcia stabilized hafnia, magnesia stabilized hafnia, and combinations thereof.

7. The method according to claim 1 wherein providing the inner ceramic layer includes providing a low conductivity thermal barrier coating composition having a lower thermal conductivity than 7 YSZ.

8. The method according to claim 1 wherein providing the inner ceramic layer includes providing the inner ceramic layer with a nominal thickness of up to about 508 microns (about 20 mils) and wherein providing the outer alumina-containing layer includes providing the outer alumina-containing layer with a nominal thickness of about 25 microns (about 1 mil).

9. The method according to claim 1 including providing the bond coat with a nominal thickness of up to about 127 microns (about 5 mils).

10. The method according to claim 1 including providing the bond coat comprising a MCrAlX overlay coating, where M is iron, cobalt and/or nickel, and X is an active element.

11. The method according to claim 1 wherein providing the inner ceramic layer includes providing the inner ceramic layer with a nominal thickness of from about 305 to about 508 microns (about 12 to about 20 mils) and providing the outer alumina-containing layer with a nominal thickness of about 25 microns (about 1 mil).

12. The method according to claim 1 wherein providing the inner ceramic layer includes providing the inner ceramic layer with a nominal thickness of from about 305 to about 508 microns (about 12 to about 20 mils) and providing the outer alumina-containing layer includes providing the outer alumina-containing layer with a nominal thickness of about 25 microns (about 1 mils), and wherein providing the first intermediate alumina-containing layer includes providing the first intermediate alumina-containing layer with a nominal thickness of up to about 25 microns (about 1 mil).

13. A method comprising:
disposing a bond coat on at least a portion of a metallic substrate;
disposing a coating over the bond coat, including:
disposing an inner ceramic layer overlying and in contact with the bond coat utilizing a deposition technique selected from a thermal spray technique, a physical vapor deposition technique, and a suspension plasma spray technique;
disposing a first intermediate alumina-containing layer overlying and in contact with the inner ceramic layer;
disposing a first intermediate ceramic layer overlying and in contact with the first intermediate alumina-containing layer; and
disposing an outer alumina-containing layer overlying and in contact with the first intermediate ceramic layer utilizing a deposition technique selected from a suspension plasma spray technique, a solution plasma spray technique, and a high velocity oxygen fuel technique, wherein the outer alumina-containing layer includes titania in an amount greater than 0% and up to about 50% by weight.

14. The method according to claim 13 including a suitable heat treatment operable to provide substantially all the alumina in at least the outer alumina-containing layer as an α-alumina form.
